(19) United States
(12) Patent Application Publication
(10) Pub. No.: US 2023/0113473 A1
(43) Pub. Date: Apr. 13, 2023

(54) PIXEL ARRANGEMENT STRUCTURE, ORGANIC ELECTROLUMINESCENT DEVICE, AND DISPLAY DEVICE

(71) Applicant: Shenzhen China Star Optoelectronics Semiconductor Display Technology Co., Ltd., Shenzhen, Guangdong (CN)

(72) Inventors: Kuo GAO, Shenzhen, Guangdong (CN); Baixiang HAN, Shenzhen, Guangdong (CN); Liuqi ZHANG, Shenzhen, Guangdong (CN); Jianxin LIU, Shenzhen, Guangdong (CN); Zhibin HAN, Shenzhen, Guangdong (CN)

(73) Assignee: Shenzhen China Star Optoelectronics Semiconductor Display Technology Co., Ltd., Shenzhen, Guangdong (CN)

(21) Appl. No.: 16/961,926

(22) PCT Filed: Apr. 15, 2020
(86) PCT No.: PCT/CN2020/084917

§ 371 Date: Jul. 14, 2020

(30) Foreign Application Priority Data
Mar. 30, 2020 (CN) 202010234988.3

(51) Int. Cl. H10K 59/35; G09G 3/30

(52) U.S. Cl. CPC H01L 27/3218; G09G 3/30

(57) ABSTRACT

A pixel arrangement structure provided by the present invention comprises a plurality of pixel groups. Each of the pixel groups comprises a first pixel, a second pixel, a third pixel, and a fourth pixel, wherein the first pixel includes a first sub-pixel and a second sub-pixel, and the second pixel includes the first sub-pixel and one second sub-pixel, two second sub-pixels in the first pixel and the second pixel share one same first sub-pixel, the third pixel and the fourth pixel both comprise a third sub-pixel and one second sub-pixel, two second sub-pixels in the third pixel and the fourth pixel share one same third sub-pixel, and the second sub-pixel is a blue sub-pixel. The invention increases the service lifespan of the blue sub-pixel.

### FIELD OF INVENTION

The present disclosure relates to the field of display technology, and more particularly, to a pixel arrangement structure, an organic electroluminescent device, and a display device.

### BACKGROUND OF INVENTION

Organic light-emitting diode (OLED) display devices have gradually become high-end display devices to replace liquid crystals due to their advantages of ultra-high contrast, wide color gamut, fast response times, active light emission, and so on. However, lifespan of blue sub-pixels in RGB sub-pixels of current OLED is the shortest, which restricts pixel design, panel brightness lifespan, and chroma lifespan. Especially, when blue light decays violently, color deviation of panels is obvious.

Therefore, how to effectively increase service lifespan of the blue sub-pixels is an important research direction for development of OLED display devices.

### SUMMARY OF INVENTION

An embodiment of the present disclosure provides a pixel arrangement structure, an organic electroluminescent device, and a display device to solve the problem of short service life of blue sub-pixels.

The present disclosure provides a pixel arrangement structure comprising a plurality of pixel groups arranged cyclically, and each of the pixel groups comprises a first pixel, a second pixel, a third pixel, and a fourth pixel. Wherein, the first pixel and the second pixel both comprise a first sub-pixel and a second sub-pixel, two second sub-pixels in the first pixel and the second pixel share one first sub-pixel, the third pixel and the fourth pixel both comprise a third sub-pixel and one second sub-pixel, two second sub-pixels in the third pixel and the fourth pixel share one third sub-pixel, and the second sub-pixel is a blue sub-pixel.

In some embodiments, the second sub-pixels of the first pixel and the second pixel are arranged in rows, and the second sub-pixels of the third pixel and the fourth pixel are arranged in rows.

In some embodiments, any four second sub-pixels share one first sub-pixel or one third sub-pixel.

In some embodiments, an area of the first sub-pixel is equal to an area of the third sub-pixel, and an area of the second sub-pixel is greater than the area of the first sub-pixel.

In some embodiments, the first sub-pixel is a red sub-pixel, and the third sub-pixel is a green sub-pixel.

In some embodiments, a brightness of the first sub-pixel and a brightness of the third sub-pixel are greater than a brightness of the second sub-pixel.

In some embodiments, the first sub-pixel and the second sub-pixel are arranged parallel to the third pixel and the fourth pixel.

In some embodiments, the first sub-pixel, the second sub-pixel, and the third sub-pixel are all quadrilateral structures.

The embodiment of the present disclosure further provides an organic electroluminescent device comprising a substrate and a pixel arrangement structure. The pixel arrangement structure is disposed on the substrate, the pixel arrangement structure comprises a plurality of pixel groups arranged cyclically, and each of the pixel groups comprises a first pixel, a second pixel, a third pixel, and a fourth pixel. Wherein, the first pixel and the second pixel both comprise a first sub-pixel and a second sub-pixel, two second sub-pixels in the first pixel and the second pixel share one first sub-pixel, the third pixel and the fourth pixel both comprise a third sub-pixel and one second sub-pixel, two second sub-pixels in the third pixel and the fourth pixel share one third sub-pixel, and the second sub-pixel is a blue sub-pixel.

In some embodiments, the second sub-pixels of the first pixel and the second pixel are arranged in rows, and the second sub-pixels of the third pixel and the fourth pixel are arranged in rows.

In some embodiments, any four second sub-pixels share one first sub-pixel or one third sub-pixel.

In some embodiments, an area of the first sub-pixel is equal to an area of the third sub-pixel, and an area of the second sub-pixel is greater than the area of the first sub-pixel.

In some embodiments, the first sub-pixel is a red sub-pixel, and the third sub-pixel is a green sub-pixel.

In some embodiments, a brightness of the first sub-pixel and a brightness of the third sub-pixel are greater than a brightness of the second sub-pixel.

In some embodiments, the first sub-pixel and the second sub-pixel are arranged parallel to the third pixel and the fourth pixel.

In some embodiments, the first sub-pixel, the second sub-pixel, and the third sub-pixel are all quadrilateral structures.

The embodiment of the present disclosure further provides a display device comprising an organic electroluminescent device. The organic electroluminescent device comprises a substrate and a pixel arrangement structure, the pixel arrangement structure is disposed on the substrate, the pixel arrangement structure comprises a plurality of pixel groups arranged cyclically, and each of the pixel groups comprises a first pixel, a second pixel, a third pixel, and a fourth pixel. Wherein, the first pixel and the second pixel both comprise a first sub-pixel and a second sub-pixel, two second sub-pixels in the first pixel and the second pixel share one first sub-pixel, the third pixel and the fourth pixel both comprise a third sub-pixel and one second sub-pixel, two second sub-pixels in the third pixel and the fourth pixel share one third sub-pixel, and the second sub-pixel is a blue sub-pixel.

In some embodiments, the second sub-pixels of the first pixel and the second pixel are arranged in rows, and the second sub-pixels of the third pixel and the fourth pixel are arranged in rows.

In some embodiments, any four second sub-pixels share one first sub-pixel or one third sub-pixel.

In some embodiments, an area of the first sub-pixel is equal to an area of the third sub-pixel, and an area of the second sub-pixel is greater than the area of the first sub-pixel.

The embodiments of the present disclosure provide the pixel arrangement structure, the organic electroluminescent device, and the display device. The pixel arrangement structure comprises the plurality of pixel groups arranged cyclically, and each of the pixel groups comprises the first pixel, the second pixel, the third pixel, and the fourth pixel. Wherein, the first pixel and the second pixel both comprise the first sub-pixel and the second sub-pixel, two second sub-pixels in the first pixel and the second pixel share one first sub-pixel, the third pixel and the fourth pixel both comprise the third sub-pixel and one second sub-pixel, two second sub-pixels in the third pixel and the fourth pixel share one third sub-pixel, and the second sub-pixel is the blue sub-pixel. In the present disclosure, two blue sub-pixels share one first sub-pixel or one third sub-pixel, thereby greatly improving aperture ratio of the blue sub-pixel, reducing current density of the blue sub-pixel, increasing service lifespan of the blue sub-pixel, and preventing display panels from color deviation.

### DESCRIPTION OF DRAWINGS

In order to more clearly explain the technical solutions in the embodiments of the present disclosure, the following will briefly introduce the drawings required in the description of the embodiments.

FIG. 1 is a schematic structural diagram of a pixel arrangement structure provided by an embodiment of the present disclosure.

FIG. 2 is a schematic structural diagram of a pixel group provided by the embodiment of the present disclosure.

FIG. 3 is a schematic structural diagram of an organic electroluminescent device provided by the embodiment of the present disclosure.

### DETAILED DESCRIPTION OF PREFERRED EMBODIMENTS

The technical solutions in the embodiments of the present disclosure will be clearly and completely described below in conjunction with accompanying drawings in the embodiments of the present disclosure. Obviously, the embodiments described are merely a part of the present disclosure, rather than all the embodiments. All other embodiments obtained by the person having ordinary skill in the art based on embodiments of the disclosure, without making creative efforts, are within the scope of the present disclosure.

The following descriptions of embodiments are with reference to additional drawings to illustrate specific embodiments that can be implemented by the present disclosure. The directional terms described by the present disclosure, such as “upper”, “lower”, “front”, “back”, “left”, “right”, “inner”, “outer”, etc., are only directions by referring to the accompanying drawings. The directional terms used herein are used to explain and explain the present disclosure, rather than to limit the present disclosure.

An embodiment of the present disclosure provides a pixel arrangement structure, an organic electroluminescent device, and a display device, and the following describes the pixel arrangement structure in detail.

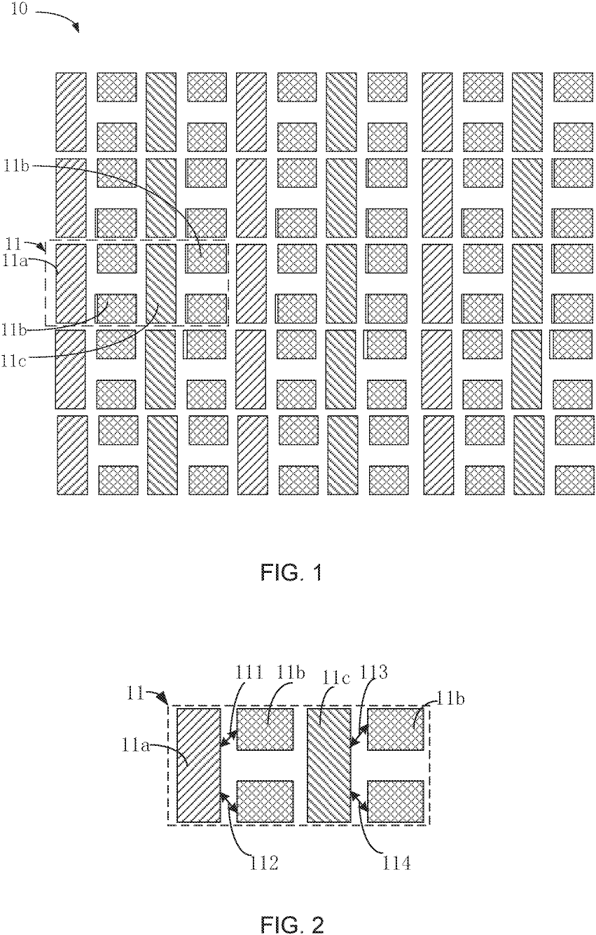

Refer to FIG. 1 and FIG. 2. FIG. 1 is a schematic structural diagram of the pixel arrangement structure provided by the embodiment of the present disclosure. FIG. 2 is a schematic structural diagram of a pixel group provided by the embodiment of the present disclosure. Wherein, the pixel arrangement structure in the present disclosure comprises a plurality of pixel groups 11 arranged cyclically, and each of the pixel groups 11 comprises a first pixel 111, a second pixel 112, a third pixel 113, and a fourth pixel 114. Wherein, the first pixel 111 and the second pixel 112 both comprise a first sub-pixel 11 a and a second sub-pixel 11 b, two second sub-pixels 11b in the first pixel 111 and the second pixel 112 share one first sub-pixel 11a, the third pixel 113 and the fourth pixel 114 both comprise a third sub-pixel 11c and one second sub-pixel 11b, two second sub-pixels 11b in the third pixel 113 and the fourth pixel 114 share one third sub-pixel 11c, and the second sub-pixel 11 b is a blue sub-pixel.

It should be noted that the plurality of pixel groups 11 are arranged parallel to form the pixel arrangement structure 10, and each of the pixel groups 11 comprises four pixels. Specifically, they comprise the first pixel 111, the second pixel 112, the third pixel 113, and the fourth pixel 114. Wherein, the first pixel 111, the second pixel 112, the third pixel 113, and the fourth pixel 114 are formed by three sub-pixels. The three sub-pixels respectively are the first sub-pixel 11a, the second sub-pixel 11b, and the third sub-pixel 11c. Specifically, the first pixel 111 is formed by the first sub-pixel 11a and the second sub-pixel 11b, the second pixel 112 is formed by the first sub-pixel 11a and the second sub-pixel 11b, the third pixel 113 is formed by the third sub-pixel 11c and the second sub-pixel 11b, and the fourth pixel 114 is formed by the third sub-pixel 11c and the second sub-pixel 11b. More specifically, two second sub-pixels 11b in the first pixel 111 and the second pixel 112 share one first sub-pixel 11a, and two second sub-pixels 11b in the third pixel 113 and the fourth pixel 114 share one third sub-pixel 11c. The first sub-pixel 11a is a red sub-pixel, the second sub-pixel 11b is a blue sub-pixel, and the third sub-pixel 11c is a green sub-pixel. In the present disclosure, two blue sub-pixels share one first sub-pixel 11a or one third sub-pixel 11c, thereby greatly improving aperture ratio of the blue sub-pixel, reducing current density of the blue sub-pixel, increasing service lifespan of the blue sub-pixel, and preventing display panels from color deviation.

Wherein, in some embodiments, the second sub-pixels 11b of the first pixel 111 and the second pixel 112 are arranged in rows, and the second sub-pixels 11b of the third pixel 113 and the fourth pixel 114 are arranged in rows.

It should be noted that an interval is defined between the second sub-pixels 11b of the first pixel 111 and the second sub-pixels 11b of the second pixel 112. In the embodiment of the present disclosure, two second sub-pixels 11b share one first sub-pixel 11a or one third sub-pixel 11c, and the second sub-pixels 11b is the blue sub-pixel. Therefore, aperture ratio of the blue sub-pixel is improved, current density of the blue sub-pixel is reduced, service lifespan of the blue sub-pixel is increased, and color deviation of display panels is prevented.

Wherein, any four second sub-pixels 11b share one first sub-pixel 11a or one third sub-pixel 11c.

It should be noted that four adjacent blue sub-pixel light-emitting units share one first sub-pixel 11a or one third sub-pixel 11c, so that current density of the blue sub-pixel is further reduced, thereby increasing service lifespan of the blue sub-pixel.

Wherein, an area of the first sub-pixel 11a is equal to an area of the third sub-pixel 11c, and an area of the second sub-pixel 11b is greater than the area of the first sub-pixel 11a.

It should be noted that the area of the second sub-pixel 11b is greater than the area of the first sub-pixel 11a or the area of the third sub-pixel 11c. Since the area of the second sub-pixel 11b is greater, current density of the blue sub-pixel is reduced and service lifespan of the blue sub-pixel is increased.

Wherein, a brightness of the first sub-pixel 11a and a brightness of the third sub-pixel 11c are greater than a brightness of the second sub-pixel 11b. It should be noted that since one first sub-pixel 11a or third sub-pixel 11c needs to be shared by two second sub-pixels, the brightness of the first sub-pixel 11a and the brightness of the third sub-pixel 11c needs to be increased to ensure the pixel arrangement structure 10 to work normally.

Wherein, the first sub-pixel 111 and the second sub-pixel 112 are arranged parallel to the third pixel 113 and the fourth pixel 114.

It should be noted that the arrangement structure is simple, the arrangement method is simple, and service lifespan of the blue sub-pixels can be improved.

Wherein, the first sub-pixel 11a, the second sub-pixel 11b, and the third sub-pixel 11c are all quadrilateral structures.

It should be noted that the first sub-pixel 11a, the second sub-pixel 11b, and the third sub-pixel 11c in present disclosure may also adopt other shapes, such as rhombic, pentagonal, etc.

The pixel arrangement structure provided by the embodiment of the present disclosure provides the plurality of pixel groups 11 arranged cyclically. Each of the pixel groups 11 comprises the first pixel 111, the second pixel 112, the third pixel 113, and the fourth pixel 114. Wherein, the first pixel 111 and the second pixel 112 both formed by the first sub-pixel 11a and the second sub-pixel 11b, two second sub-pixels 11b in the first pixel 111 and the second pixel 112 share one first sub-pixel 11a, the third pixel 113 and the fourth pixel 114 both comprise the third sub-pixel 11c and one second sub-pixel 11b, two second sub-pixels 11b in the third pixel 113 and the fourth pixel 114 share one third sub-pixel 11c, and the second sub-pixel 11b is the blue sub-pixel. In the present disclosure, two blue sub-pixels share one first sub-pixel 11a or one third sub-pixel 11c, thereby greatly improving aperture ratio of the blue sub-pixel, reducing current density of the blue sub-pixel, increasing service lifespan of the blue sub-pixel, and preventing display panels from color deviation.

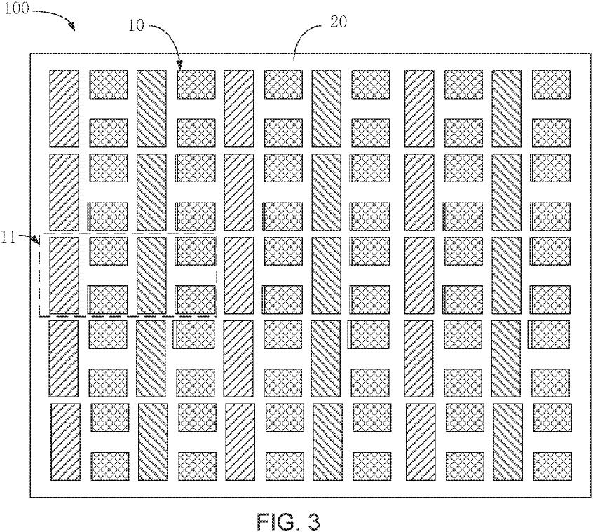

Refer to FIG. 3, FIG. 3 is a schematic structural diagram of an organic electroluminescent device provided by the embodiment of the present disclosure. The present disclosure further provides an organic electroluminescent device 100 comprising a substrate 20 and a pixel arrangement structure 10. The pixel arrangement structure 10 is disposed on the substrate 20, and the pixel arrangement structure 10 is the above pixel arrangement structure 10. Since the pixel arrangement structure 10 has been described in detail in the above embodiments, the pixel structure is not described in detail in the present disclosure. In addition, the organic electroluminescent device 100 of the present disclosure also has all the effective effects of the above pixel arrangement structure 10.

Wherein, a display device comprises an organic electroluminescent device 100. The organic electroluminescent device 100 has been described in detail in the above embodiments, and will not be described in detail in the embodiments of the present disclosure.

The pixel arrangement structure, the organic electroluminescent device, and the display device provided by the embodiments of the present disclosure are described in detail. This article uses specific examples to explain the principles and implementation of the present disclosure. The descriptions of the above examples are only used to help understand the present disclosure. Meanwhile, for those skilled in the art, according to the ideas of the present disclosure, there will be changes in the specific implementation mode and application scope. In summary, the content of this specification should not be understood as a limitation of the present disclosure.

1. A pixel arrangement structure, comprising:
a plurality of pixel groups arranged cyclically, and each of the pixel groups comprises a first pixel, a second pixel, a third pixel, and a fourth pixel;
wherein the first pixel and the second pixel both comprise a first sub-pixel and a second sub-pixel the first pixel comprises a first sub-pixel and a second sub-pixel, and the second pixel comprises the first sub-pixel and one second sub-pixel;
two second sub-pixels in the first pixel and the second pixel share one same first sub-pixel;
the third pixel and the fourth pixel both comprise a third sub-pixel and one second sub-pixel;
two second sub-pixels in the third pixel and the fourth pixel share one same third sub-pixel; and
the second sub-pixel is a blue sub-pixel.

2. The pixel arrangement structure as claimed in claim 1, wherein the second sub-pixels of the first pixel and the second pixel are arranged in rows, and the second sub-pixels of the third pixel and the fourth pixel are arranged in rows.

3. The pixel arrangement structure as claimed in claim 2, wherein any four second sub-pixels share one first sub-pixel or one third sub-pixel.

4. The pixel arrangement structure as claimed in claim 1, wherein an area of the first sub-pixel is equal to an area of the third sub-pixel, and an area of the second sub-pixel is greater than the area of the first sub-pixel.

5. The pixel arrangement structure as claimed in claim 1, wherein the first sub-pixel is a red sub-pixel, and the third sub-pixel is a green sub-pixel.

6. The pixel arrangement structure as claimed in claim 1, wherein a brightness of the first sub-pixel and a brightness of the third sub-pixel are greater than a brightness of the second sub-pixel.

7. The pixel arrangement structure as claimed in claim 1, wherein the first sub-pixel and the second sub-pixel are arranged parallel to the third pixel and the fourth pixel.

8. The pixel arrangement structure as claimed in claim 1, wherein the first sub-pixel, the second sub-pixel, and the third sub-pixel are all quadrilateral structures.

9. An organic electroluminescent device, comprising a substrate and a pixel arrangement structure, wherein the pixel arrangement structure is disposed on the substrate, the pixel arrangement structure comprises a plurality of pixel groups arranged cyclically, and each of the pixel groups comprises a first pixel, a second pixel, a third pixel, and a fourth pixel;
wherein the first pixel and the second pixel both comprise a first sub-pixel and a second sub-pixel the first pixel comprises a first sub-pixel and a second sub-pixel, and the second pixel comprises the first sub-pixel and one second sub-pixel;
two second sub-pixels in the first pixel and the second pixel share one same first sub-pixel;
the third pixel and the fourth pixel both comprise a third sub-pixel and one second sub-pixel;
two second sub-pixels in the third pixel and the fourth pixel share one same third sub-pixel; and
the second sub-pixel is a blue sub-pixel.

10. The organic electroluminescent device as claimed in claim 9, wherein the second sub-pixels of the first pixel and the second pixel are arranged in rows, and the second sub-pixels of the third pixel and the fourth pixel are arranged in rows.

11. The organic electroluminescent device as claimed in claim 10, wherein any four second sub-pixels share one first sub-pixel or one third sub-pixel.

12. The organic electroluminescent device as claimed in claim 9, wherein an area of the first sub-pixel is equal to an area of the third sub-pixel, and an area of the second sub-pixel is greater than the area of the first sub-pixel.

13. The organic electroluminescent device as claimed in claim 9, wherein the first sub-pixel is a red sub-pixel, and the third sub-pixel is a green sub-pixel.

14. The organic electroluminescent device as claimed in claim 9, wherein a brightness of the first sub-pixel and a brightness of the third sub-pixel are greater than a brightness of the second sub-pixel.

15. The organic electroluminescent device as claimed in claim 9, wherein the first sub-pixel and the second sub-pixel are arranged parallel to the third pixel and the fourth pixel.

16. The organic electroluminescent device as claimed in claim 9, wherein the first sub-pixel, the second sub-pixel, and the third sub-pixel are all quadrilateral structures.

17. A display device, comprising an organic electroluminescent device, wherein the organic electroluminescent device comprises a substrate and a pixel arrangement structure, the pixel arrangement structure is disposed on the substrate, the pixel arrangement structure comprises a plurality of pixel groups arranged cyclically, and each of the pixel groups comprises a first pixel, a second pixel, a third pixel, and a fourth pixel;
wherein the first pixel and the second pixel both comprise a first sub-pixel and a second sub-pixel the first pixel comprises a first sub-pixel and a second sub-pixel, and the second pixel comprises the first sub-pixel and one second sub-pixel;
two second sub-pixels in the first pixel and the second pixel share one same first sub-pixel;
the third pixel and the fourth pixel both comprise a third sub-pixel and one second sub-pixel;
two second sub-pixels in the third pixel and the fourth pixel share one same third sub-pixel; and
the second sub-pixel is a blue sub-pixel.

18. The display device as claimed in claim 17, wherein the second sub-pixels of the first pixel and the second pixel are arranged in rows, and the second sub-pixels of the third pixel and the fourth pixel are arranged in rows.

19. The display device as claimed in claim 18, wherein any four second sub-pixels share one first sub-pixel or one third sub-pixel.

20. The display device as claimed in claim 17, wherein an area of the first sub-pixel is equal to an area of the third sub-pixel, and an area of the second sub-pixel is greater than the area of the first sub-pixel.
